(19) United States
(12) Patent Application Publication
(10) Pub. No.: US 2014/0103405 A1
(43) Pub. Date: Apr. 17, 2014

(54) METHOD FOR FABRICATING SEMICONDUCTOR DEVICE

(71) Applicant: Samsung Electronics Co., Ltd., Suwon-si (KR)

(72) Inventors: Chong-Kwang Chang, Bucheon-si (KR); Hak-Yoon Ahn, Seoul (KR); Young-Mook Oh, Hwaseong-si (KR); Jung-Hoon Lee, Hwaseong-si (KR); Seung-Ho Chae, Hwaseong-si (KR)

(73) Assignee: Samsung Electronics Co., Ltd., Suwon-si (KR)

(21) Appl. No.: 13/948,696

(22) Filed: Jul. 23, 2013

(30) Foreign Application Priority Data
Oct. 15, 2012 (KR) 10-2012-0114268

(51) Int. Cl. H01L 29/78; H01L 21/302; H01L 29/66

(52) U.S. Cl. CPC H01L 29/78; H01L 29/66477; H01L 21/302
USPC 257/288; 438/299; 438/702

(57) ABSTRACT

A method is provided for fabricating a semiconductor device that includes: forming a gate pattern on a substrate; forming a source/drain in the vicinity of the gate pattern; forming an etch stop film, which covers the gate pattern and the source/drain, on the substrate; forming an interlayer insulating film on the etch stop film; forming a shared contact hole that exposes the gate pattern and the source/drain by etching the interlayer insulating film, wherein a polymer is generated in the shared contact hole a process of etching the interlayer insulating film; removing the polymer by performing etching using hydrogen gas, nitrogen gas or a mixture of hydrogen and nitrogen before etching the etch stop film; and etching the etch stop film.

### CROSS-REFERENCE TO RELATED APPLICATIONS

This application is based on and claims priority from Korean Patent Application No. 10-2012-0114268, filed on Oct. 15, 2012 in the Korean Intellectual Property Office, the disclosure of which is incorporated herein in its entirety by reference.

### BACKGROUND

1. Field of the Inventive Concept

The present inventive concept relates generally to a method for fabricating a semiconductor device.

2. Description of the Prior Art

The technology in this field has favored smaller sized semiconductor devices to accommodate smaller sized end products that utilize the semiconductor devices. As the size of a semiconductor device is gradually decreased, a distance between gate electrodes, a distance between contacts, or a distance between a gate electrode and a contact must correspondingly be reduced. It is important to do so, however, without adversely affecting the performance properties of the semiconductor device.

### SUMMARY

One subject to be solved by the present inventive concept is to provide a method for fabricating a semiconductor device, which includes steps for removing a polymer that is generated in a shared contact hole.

Another subject to be solved by the present inventive concept is to provide a method for fabricating a semiconductor device, which includes steps for removing a polymer that is generated in a contact hole.

Additional advantages, subjects, and features of the inventive concept will be set forth in part in the description which follows and in part will become apparent to those having ordinary skill in the art upon examination of the following description, read in conjunction with the accompanying drawings, or which may be learned from practice of the inventive concept.

In order to accomplish the subject, there is provided a method for fabricating a semiconductor device comprising the steps of: forming a gate pattern on a substrate and forming a source/drain in the vicinity of the gate pattern; forming an etch stop film, which covers the gate pattern and the source/drain, on the substrate; forming an interlayer insulating film on the etch stop film; forming a shared contact hole that exposes the gate pattern and the source/drain by etching the interlayer insulating film, wherein a polymer is generated in the shared contact hole in a process of etching the interlayer insulating film; removing the polymer by performing etching using hydrogen gas, nitrogen gas or a mixture of hydrogen and nitrogen; and etching the etch stop film.

In order to accomplish another subject, there is provided a method for fabricating a semiconductor device comprising the steps of: forming a gate pattern on a substrate and forming a source/drain in the vicinity of the gate pattern; forming an etch stop film, which covers the gate pattern and the source/drain, on the substrate; forming an interlayer insulating film on the etch stop film; forming a mask pattern on the interlayer insulating film; forming a contact hole that exposes the source/drain by etching the interlayer insulating film, wherein a polymer is generated in the contact hole in a process of etching the interlayer insulating film; ashing the mask pattern; removing the polymer by performing etching using hydrogen gas, nitrogen gas or a mixture of hydrogen and nitrogen; and etching the etch stop film.

### BRIEF DESCRIPTION OF THE DRAWINGS

The above and other objects, features and advantages of the present inventive concept will be more apparent from the following detailed description taken in conjunction with the accompanying drawings, in which:

FIGS. 1 to 7 are views explaining a method for fabricating a semiconductor device according to a first illustrative embodiment of the present inventive concept;

FIG. 8 is a view explaining a method for fabricating a semiconductor device according to a second illustrative embodiment of the present inventive concept;

FIG. 9 is a view explaining a method for fabricating a semiconductor device according to a third illustrative embodiment of the present inventive concept;

FIGS. 10 and 11 are views explaining a method for fabricating a semiconductor device according to a fourth illustrative embodiment of the present inventive concept;

FIGS. 12 and 13 are views explaining a method for fabricating a semiconductor device according to a fifth illustrative embodiment of the present inventive concept;

FIG. 14 is a block diagram of an electronic system including a semiconductor device according to some embodiments of the present inventive concept; and

FIGS. 15 and 16 are exemplary views of an electronic system to which the semiconductor device according to some embodiments of the present inventive concept can be applied.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification and drawings. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (e.g., rotated 90 degrees or at other orientations) and the spatially relative descriptors used herein are intended to be interpreted accordingly.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein, is intended merely to better illuminate the invention and is not a limitation on the scope of the invention unless otherwise specified. Further, unless defined otherwise, all terms defined in generally used dictionaries are intended to be interpreted consistent with such common dictionary definitions.

The present invention will be described with reference to perspective views, cross-sectional views, and/or plan views, in which preferred embodiments of the invention are shown. But, it should be understood that the profile of an exemplary view may be modified according to manufacturing techniques and/or allowances. That is, the illustrated embodiments of the invention are not intended to limit the scope of the present invention; but rather, this application and the accompanying claims should be construed to cover all changes and modifications that can be caused due to a change in manufacturing process. Thus, regions shown in the drawings are illustrated in schematic form and the shapes of the regions are presented simply by way of illustration and not as a limitation.

A method for fabricating a semiconductor device as described hereinafter relates to forming a shared contact after removing a polymer that is generated in a shared contact hole. Recently, in order to decrease a margin and to reduce an area that is occupied by contacts, a shared contact process has been introduced. The shared contact functions as a contact in an area which is shared by a part of a gate pattern area and a part of a source/drain area.

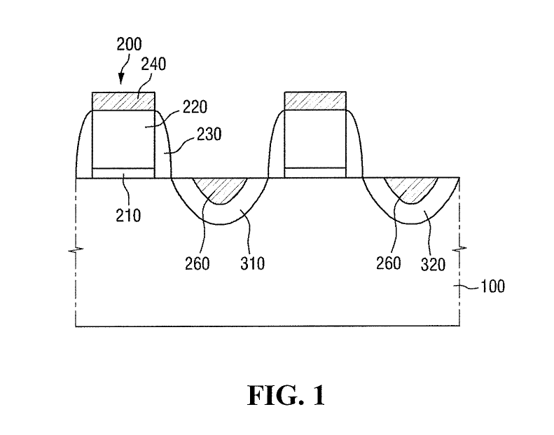

FIGS. 1 to 7 are views explaining a method for fabricating a semiconductor device according to an embodiment of the present inventive concept.

First, referring to FIG. 1, a gate pattern 200 and a source/drain 310 or 320 are formed on a substrate 100.

The substrate 100 may be made of one or more semiconductor materials selected from the group consisting of Si, Ge, SiGe, GaP, GaAs, SiC, SiGeC, InAs, and InP. Further, the substrate 100 may be an SOI (Silicon On Insulator) substrate, or may be a rigid substrate such as a glass substrate for display, or a flexible plastic substrate made of polyimide, polyester, polycarbonate, polyethersulfone, polymethylmethacrylate, polyethylenenaphthalate, polyethyleneterephthalate, or the like.

The gate pattern 200 may include a gate insulating film 210, a gate electrode 220, a spacer 230, and a silicide 240.

The gate insulating film 210 may be a silicon oxide film, a silicon nitride film, SiON, GexOyNz, GexSiyOz, a high-k material, a combination thereof, or a laminated film in which the above materials are laminated in order. Here, the high-k material may be made of, but is not limited to, LaO2, HfO2, ZrO2, Al2O3, Ta2O5, hafnium silicate, zirconium silicate, or a combination thereof.

The gate electrode 220 is formed on the gate insulating film 210. The gate electrode 220 may be, but is not limited to, a single film made of a metal, such as poly-Si, poly-SiGe, poly-Si doped with impurities, TaN, TaSiN, TiN, TaC, Mo, Ru, Ni, NiSi, W, or Al, or a metal silicide, or a laminated film in which two or more of the above materials are combined.

The spacer 230 is formed on a side wall of the gate electrode 220. The spacer 230 may include at least one of SiO2, SiN, SiON, and a low-k material (for example, SiOF, SiOC, or the like).

The silicide 240 is formed on the gate electrode 220. The silicide 240 may include, but is not limited to, at least one of NiPtSi, NiSi, CoSi, and TiSi.

The source/drain 310 or 320 is located in the substrate 100 on both sides of the gate pattern 200. A silicide 260 may be formed in the source/drain 310 or 320. The silicide 260 may include, but is not limited to, at least one of NiPtSi, NiSi, CoSi, and TiSi. The source/drain 310 or 320 may include SiGe and SiC. The source/drain 310 or 320 may have any shape. For example, the source/drain 310 or 320 may have a structure of LDD (Lightly Doped Drain), DDD (Double Diffused Drain), MIDDD (Mask Islanded Double Diffused Drain), MLDD (Mask LDD), or LDMOS (Lateral Double-diffused MOS).

Unlike the source/drain 310 or 320 illustrated in FIG. 1, the source/drain may also be an elevated source/drain. In this case, the upper surface of the source/drain 310 or 320 may be higher than the upper surface of the substrate 100. The source/drain 310 or 320 may be formed in recesses formed on both sides of the gate pattern 200 through an epitaxy process.

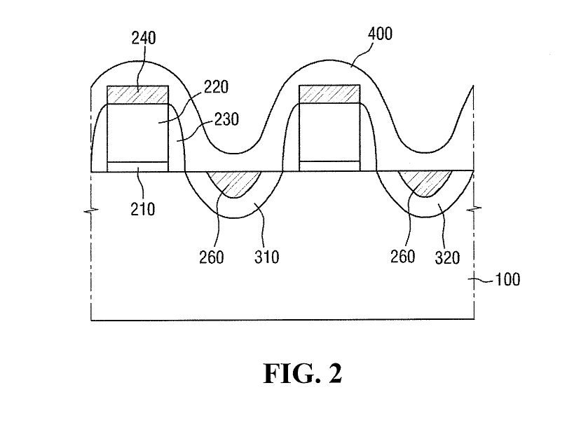

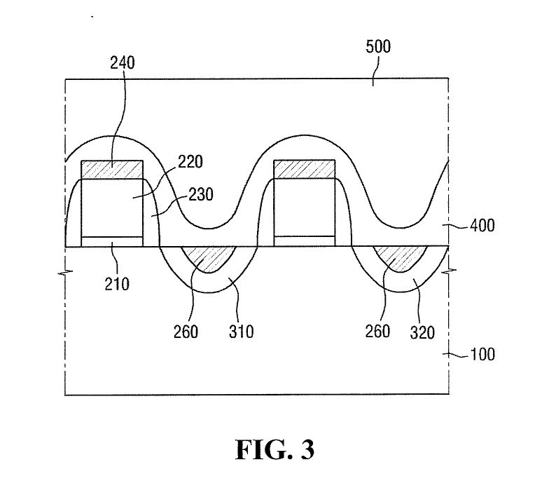

Next, referring to FIGS. 2 and 3, an etch stop film 400 and an interlayer insulating film 500 are sequentially formed.

The etch stop film 400 is formed to cover the gate pattern 200 and the source/drain 310 or 320. The etch stop film 400 may be formed of a material having an etch selectivity relative to the interlayer insulating film 500. The etch stop film 400 may be a silicon nitride (SiN) film, a silicon carbide (SiC) film, or a BCB (BenzoCycloButene) organic insulating film. The etch stop film 400 may be formed by an LPCVD (Low Pressure Chemical Vapor Deposition) method, an ALD (Atomic Layer Deposition) method, or a PECVD (Plasma Enhanced Chemical Vapor Deposition) method.

The interlayer insulating film 500 is formed on the etch stop film 400. The interlayer insulating film 500 may include at least one of SiO2, SiN, SiON, and a low-k material (for example, SiOF or SiOC).

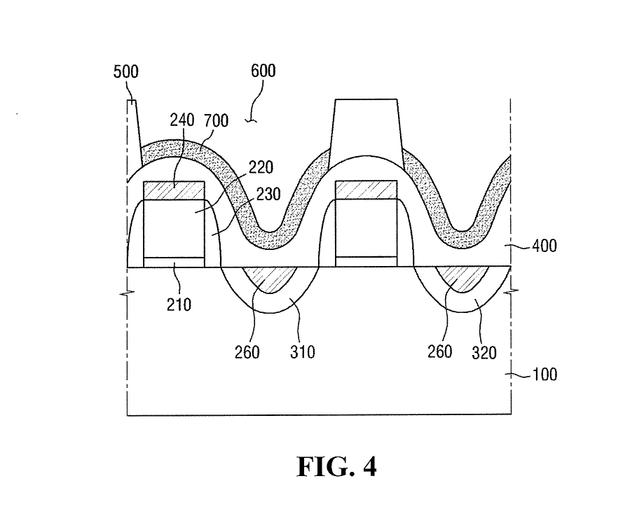

Then, referring to FIG. 4, a shared contact hole 600 (spanning gate pattern 200 and the adjacent source/drain) is formed by etching the interlayer insulating film 500.

The shared contact hole 600 is formed to expose at least the etch stop film 400 covering the gate pattern 200 and the source/drain 310 or 320. When the shared contact hole 600 is formed, a polymer 700 that is a residual product in the process of etching the interlayer insulating film 500 may be generated in the shared contact hole 600.

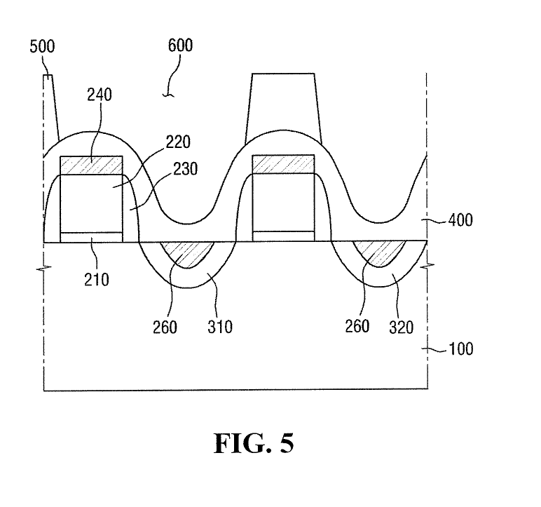

Then, referring to FIG. 5, the polymer 700 if present is removed.

If the polymer 700 is not removed, a problem may occur in the following steps of the semiconductor device fabrication process. If the etch stop film 400 is etched when it is in a state where the polymer 700 is present, the polymer 700 serves as a mask and an etching range of the etch stop film 400 is reduced. Such incomplete etching of etch stop film 400 may result in reducing an area of a bottom surface of the shared contact hole 600 which, in turn, causes an increase of contact resistance. It is therefore desirable to remove polymer 700 prior to the step of etching the etch stop film 400.

The polymer 700 is removed by performing etching using hydrogen gas, nitrogen gas or a mixture of hydrogen and nitrogen. By using hydrogen or nitrogen in the removal of polymer 700, etching by both a chemical method and also by a physical method may be performed. The hydrogen or the nitrogen has a light weight and a good linearity. Accordingly, removal of the polymer 700 can be assisted by accelerating the delivery of hydrogen or nitrogen to the surface of polymer 700 to increase the force of the collision with the polymer 700. By performing etching by a chemical method, the polymer 700 may be precisely removed. The hydrogen or the nitrogen may be used singly or together.

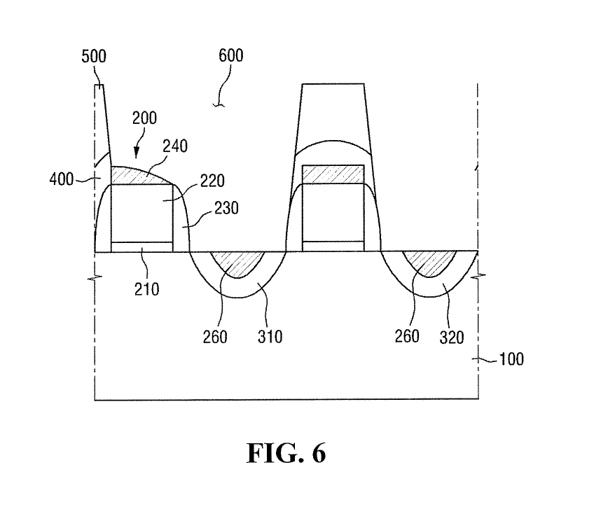

Then, referring to FIG. 6, the etch stop film 400 is etched.

The etch stop film 400 is etched until the gate pattern 200 and the source/drain 310 or 320 are exposed by the contact hole 600.

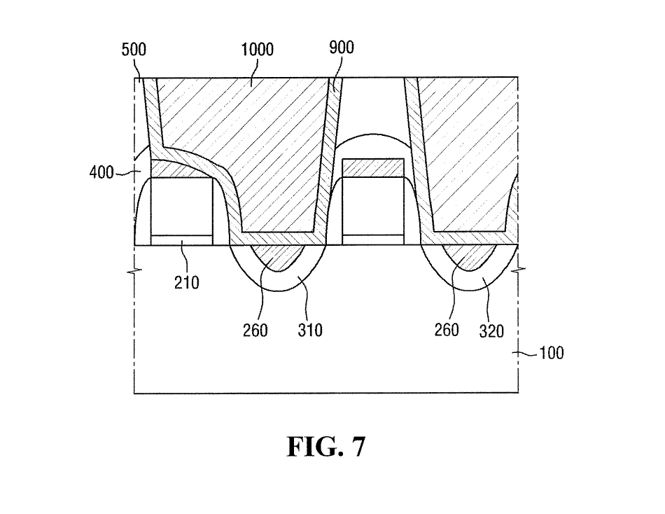

Then, referring to FIG. 7, a shared contact may be formed by first forming a barrier metal 900 and then filling the shared contact hole 600 over barrier metal 900 with a conductive film 1000.

The barrier metal 900 is formed to cover the side wall and the bottom surface of the shared contact hole 600 and the side wall and the upper portion of the gate pattern 200 after the etch stop film 400 is etched. The barrier metal 900 may be a laminated film of Ti and TiN. If only a Ti film is used, a volume of the shared contact may be reduced, and thus the EM (Electro-Migration) characteristics may be weak. To prevent this, a TiN film is preferably further formed.

The barrier metal 900 may be formed by ALD (Atomic Layer Deposition). Alternatively, in the case where the barrier metal 900 is formed by CVD (Chemical Vapor Deposition), inferiority may occur in the process of filling the shared contact hole 600 with the conductive film 1000. That is, WF6 gas may pass through the TiN film in the process of filling contact hole 600 with the conductive film 1000 (for example, W). At this time, the WF6 gas may meet Ti to generate TiFx, which is a non-conductor.

Further, in the case where the barrier metal 900 is formed by an ALD process, the barrier metal 900 can be formed more precisely than in the case where the barrier metal 900 is formed by a CVD process. As the size of a semiconductor device becomes gradually reduced, an ALD process becomes more important, especially with respect to products in the range of 45 nm or less. That is, with respect to products of 45 nm or less, it is difficult to form the barrier metal 900 with the desired degree of precision using a CVD process. The conductive film 1000 may include W, Cu, or Al.

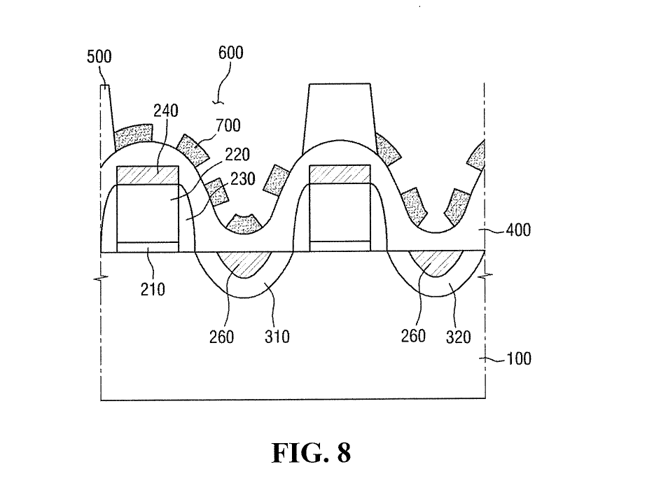

FIG. 8 is a view explaining a method for fabricating a semiconductor device according to another embodiment of the present inventive concept. For convenience in this explanation, the explanation of FIG. 8 will emphasize portions of this embodiment that are different from those in the method for fabricating a semiconductor device according to the embodiment of FIGS. 1 to 7 of the present inventive concept.

Referring to FIG. 8, in the method for fabricating a semiconductor device according to this embodiment of the present inventive concept, the steps for removing the polymer 700 may include removing a first part of the polymer 700 using a first processing condition and removing the remaining polymer 700 using a second processing condition. Comparing FIG. 8 with FIG. 4 it can be seen in FIG. 8 that only a part of the polymer 700 has been removed using a first processing condition. The part of polymer 700 that is shown as still remaining on etch stop film 400 is to be removed using the second processing condition.

The first processing condition in the embodiment of FIG. 8 is a condition where at least one of hydrogen and nitrogen is used. The second processing condition is also a condition where at least one of hydrogen and nitrogen is used, but it is different in some way from the first processing condition. For example, the first processing condition may be performing the first part of the etching of polymer 700 using hydrogen; and, the second processing condition may be performing the second part of the etching using nitrogen or using a combination of both hydrogen and nitrogen.

Further, for example, in the first processing condition and the second processing condition, the same gas may be used, but different processing atmospheres or temperatures may be used to create different processing conditions.

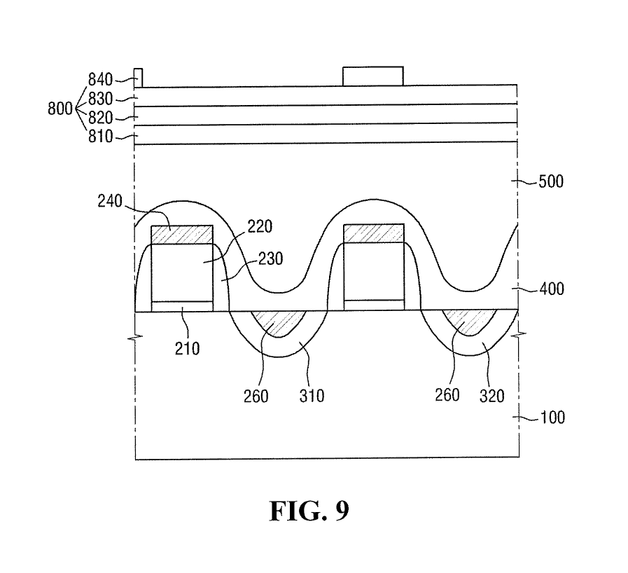

FIG. 9 is a view explaining a method for fabricating a semiconductor device according to still another embodiment of the present inventive concept. For convenience in this explanation, the explanation of FIG. 9 will emphasize portions of this embodiment that are different from those in the method for fabricating a semiconductor device according to the embodiments of FIGS. 1 to 8 of the present inventive concept.

Referring to FIG. 9, the method for fabricating a semiconductor device according to this embodiment of the present inventive concept may further include forming a mask pattern 800 between the steps of forming the interlayer insulating film 500 and etching the interlayer insulating film 500.

The steps of forming the mask pattern 800 may include sequentially forming a mask film 810, a capping film 820, a BARC (Bottom Anti Reflection Coating) film 830, and a photoresist pattern 840.

The mask film 810 is formed on the interlayer insulating film 500. The mask film 810 may be an ACL (Amorphous Carbon Layer) or a SOH (Spin-On Hard mask).

The capping film 820 is formed on the mask film 810. The capping film 820 may be made of SiON or SiN. The BARC film 830 is formed on the capping film 820.

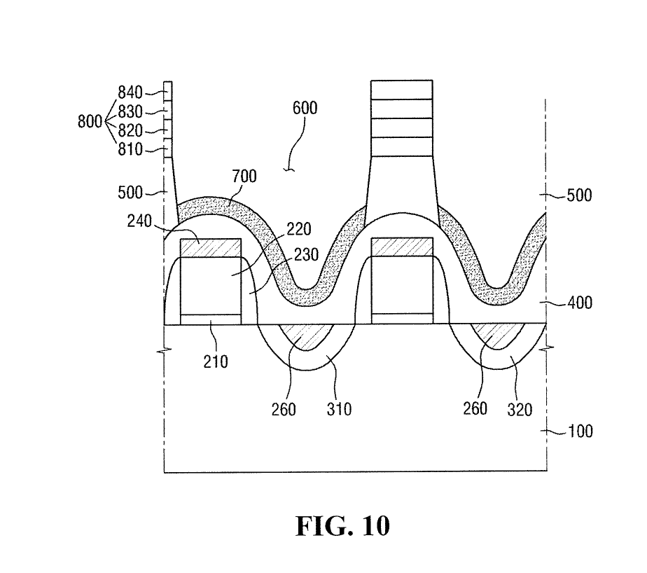

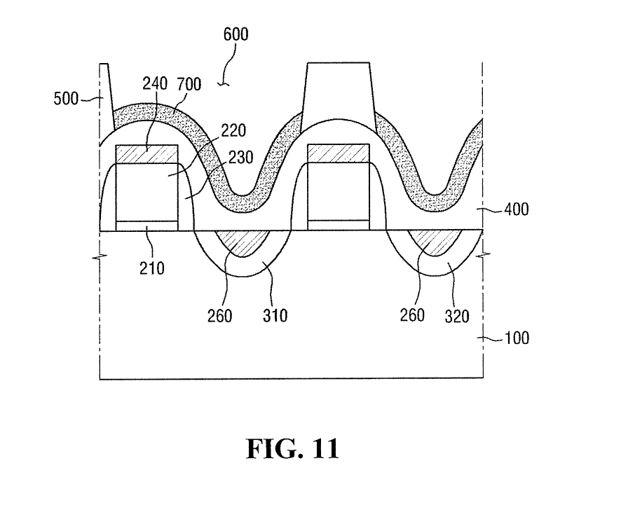

The photoresist pattern 840 is formed on the BARC film 830. The photoresist pattern 840 is patterned so that photoresist is not located above the gate pattern 200 or the source/drain 310 or 320 (i.e., these areas are left exposed). In other words, the photoresist pattern 840 is patterned to form the shared contact hole, for example through the process described below in connection with FIGS. 10 and 11.

FIGS. 10 and 11 are views explaining a method for fabricating a semiconductor device according to still another embodiment of the present inventive concept. For convenience in this explanation, the explanation of FIGS. 10 and 11 will emphasize portions of this embodiment that are different from those in the methods for fabricating a semiconductor device according to the embodiments of FIGS. 1 to 9 of the present inventive concept.

Referring to FIGS. 10 and 11, the method for fabricating a semiconductor device according to still another embodiment of the present inventive concept may further include the step of ashing the mask pattern 800 between the steps of etching the interlayer insulating film 500 to create contact hole 600 and removing the polymer 700.

In the order of processing, it is efficient to etch the interlayer insulating film 500, to ash the remaining portions of mask pattern 800, and then to remove the polymer 700. The reason for preferring this processing order is because, if the ashing is performed after the silicide 260 (that is formed in the source/drain 310 or 320) is exposed, the silicide 260 may be oxidized. The oxidized silicide 260 may act as a resistor. The step of ashing the mask pattern 800 may include performing the ashing in-situ in the same chamber as that used for etching the interlayer insulating film 500. By using this in-situ process, unnecessary and undesirable oxidation of silicide 260 is prevented.

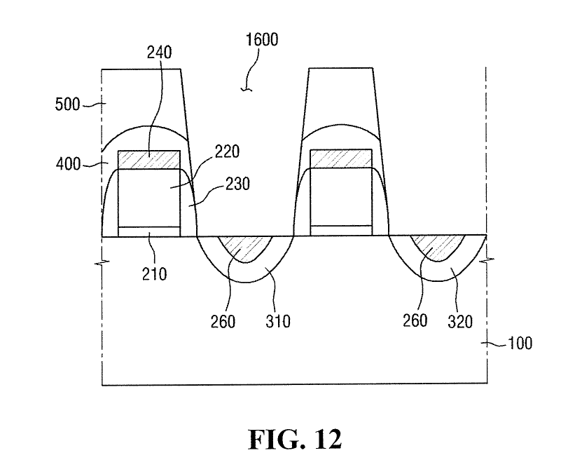

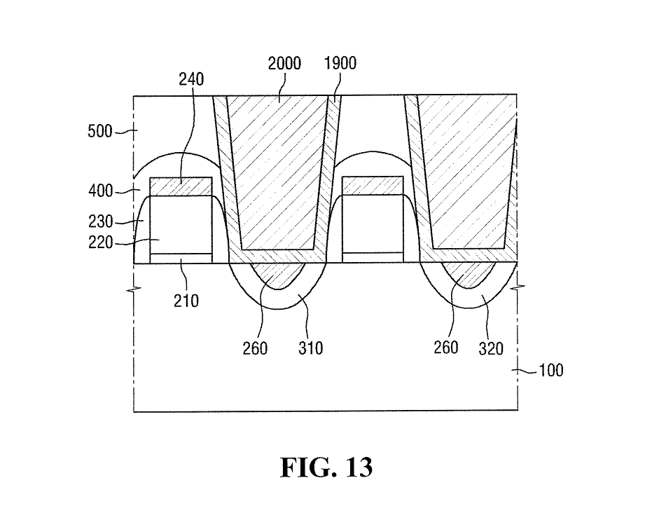

FIGS. 12 and 13 are views explaining a method for fabricating a semiconductor device according to still another embodiment of the present inventive concept. For convenience in this explanation, the explanation of FIGS. 12 and 13 will emphasize portions of this embodiment that are different from those in the methods for fabricating a semiconductor device according to the embodiments of FIGS. 1 to 11 of the present inventive concept.

Referring to FIGS. 12 and 13, in the method for fabricating a semiconductor device according to still another embodiment of the present inventive concept, a contact hole 1600 may be formed, and a contact may be formed by filling the contact hole 1600 with a conductive film 2000.

The contact hole 1600 is formed to expose the source/drain 310 or 320. While the contact hole 1600 is being formed, a polymer that is a residual product in the process of etching the interlayer insulating film 500 (as seen in FIGS. 3 and 9) may be generated in the contact hole 1600. The polymer is removed by performing etching using hydrogen and/or nitrogen, as previously described. The steps of removing the polymer may include removing a part of the polymer using a first processing condition, and removing the remaining polymer using a second processing condition that is different from the first processing condition, again as described previously.

A barrier metal 1900 is formed to cover a side wall and a bottom surface of the contact hole 1600 after etching the etch stop film 400. The barrier metal 1900 may be formed by ALD. A contact may then be formed by filling the contact hole 1600 with a conductive film 2000 over the barrier metal 1900.

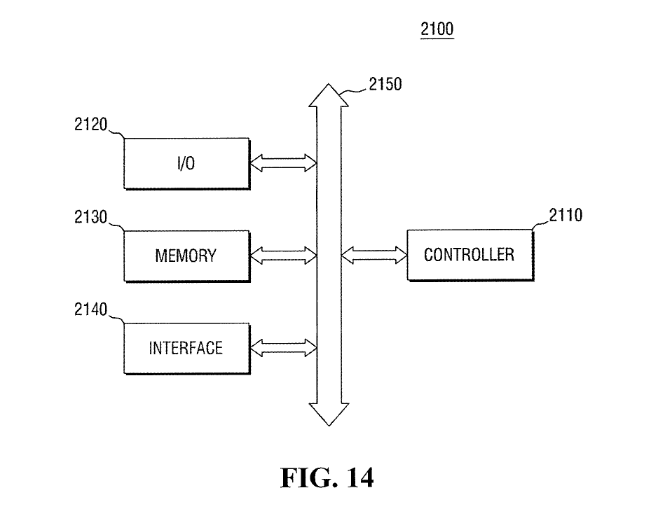

FIG. 14 is a block diagram of an electronic system including a semiconductor device fabricated according to some embodiments of the present inventive concept.

Referring to FIG. 14, an electronic system 2100 according to an embodiment of the present inventive concept may include a controller 2110, an input/output (I/O) device 2120, a memory device 2130, an interface 2140, and a bus 2150, one or more of which may include one or more semiconductor devices according to some embodiments of the present inventive concept. The controller 2110, the I/O device 2120, the memory device 2130, and/or the interface 2140 may be coupled to one another through the bus 2150. The bus 2150 corresponds to paths through which data is transferred.

The controller 2110 may include at least one of a microprocessor, a digital signal processor, a microcontroller, and logic elements that can perform similar functions. The I/O device 2120 may include a keypad, a keyboard, and a display device. The memory device 2130 may store data and/or commands. The interface 2140 may function to transfer the data to a communication network or receive the data from the communication network. The interface 2140 may be of a wired or wireless type. For example, the interface 2140 may include an antenna or a wire/wireless transceiver. Although not illustrated, the electronic system 2100 may further include a high-speed DRAM and/or SRAM as an operating memory for improving the operation of the controller 2110. Thin film transistors which include one or more semiconductor devices according to some embodiments of the present inventive concept may be provided inside the memory device 2130 or may be provided as a part of the controller 2110 and the I/O device 2120.

The electronic system 2100 may be applied to a PDA (Personal Digital Assistant), a portable computer, a web tablet, a wireless phone, a mobile phone, a digital music player, a memory card, or all electronic devices that can transmit and/or receive information in wireless environments.

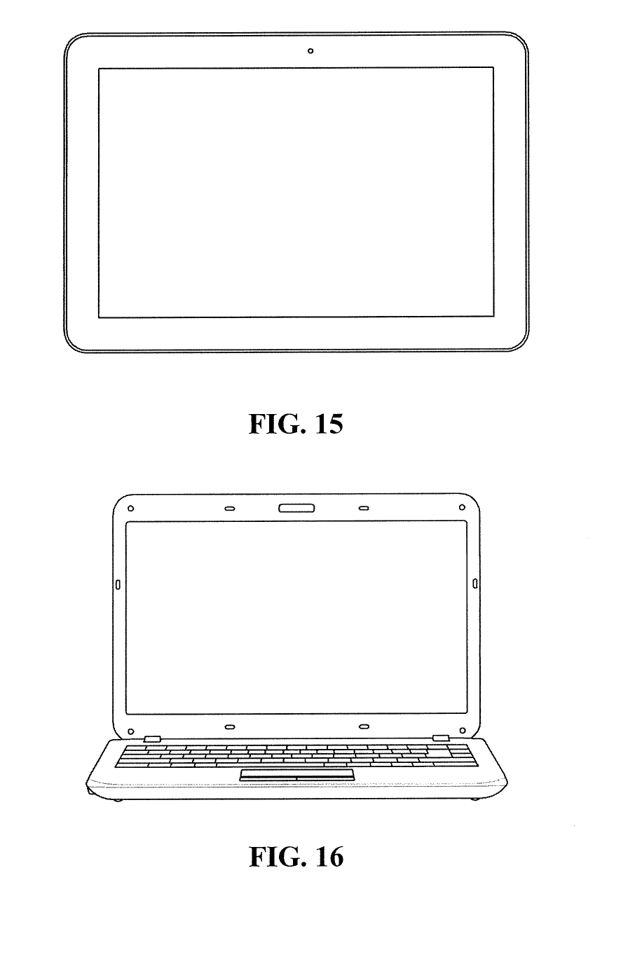

FIGS. 15 and 16 are exemplary views of apparatuses that include a semiconductor system which includes one or more of the semiconductor devices according to some embodiments of the present inventive concept. FIG. 15 illustrates a tablet PC, and FIG. 16 illustrates a notebook PC. At least one of the semiconductor devices according to some embodiments of the present inventive concept can be incorporated into the tablet PC or the notebook PC illustrated in FIGS. 15 and 16. It is apparent to those skilled in the art that semiconductor devices according to some embodiments of the present inventive concept can also be incorporated into other integrated circuit devices that have not been exemplified.

Although preferred embodiments of the present inventive concept have been described for illustrative purposes, those skilled in the art will appreciate that various modifications, additions and substitutions are possible, without departing from the scope and spirit of the inventive concept as disclosed in the accompanying claims.

What is claimed is:

1. A method for fabricating a semiconductor device, comprising:
forming a gate pattern on a substrate and forming a source/drain in the vicinity of the gate pattern;
forming an etch stop film, which covers the gate pattern and the source/drain, on the substrate;
forming an interlayer insulating film on the etch stop film;
etching the interlayer insulating film to form a shared contact hole that exposes the gate pattern and the source/drain, wherein a polymer is generated in the shared contact hole in a process of etching the interlayer insulating film;
removing the polymer by performing etching using hydrogen gas, nitrogen gas or a mixture of hydrogen and nitrogen before etching the etch stop film; and
etching the etch stop film.

2. The method for fabricating a semiconductor device of claim 1, wherein the steps for removing the polymer comprise removing part of the polymer using a first processing condition, and removing remaining polymer using a second processing condition that is different from the first processing condition.

3. The method for fabricating a semiconductor device of claim 2, wherein the first processing condition for removing the polymer is a condition where at least one of hydrogen and nitrogen is used, and the second processing condition is also a condition where at least one of hydrogen and nitrogen is used, but is different from the first processing condition.

4. The method for fabricating a semiconductor device of claim 2, wherein in the first and second processing conditions, the same gas or gas mixture is used, but different processing atmospheres and/or different temperatures are used.

5. The method for fabricating a semiconductor device of claim 1, further comprising the step of forming a mask pattern between the steps of forming the interlayer insulating film and etching the interlayer insulating film.

6. The method for fabricating a semiconductor device of claim 5, further comprising the step of ashing the mask pattern between the steps of etching the interlayer insulating film and removing the polymer.

7. The method for fabricating a semiconductor device of claim 6, wherein the step of ashing the mask pattern comprises performing the ashing in-situ in the same chamber as that for use in the etching the interlayer insulating film.

8. The method for fabricating a semiconductor device of claim 6, further comprising forming a barrier metal that covers a side wall and a bottom surface of the shared contact hole and a side wall and an upper portion of the gate pattern after the step of etching the etch stop film, and thereafter forming a shared contact by filling the shared contact hole with a conductive film.

9. The method for fabricating a semiconductor device of claim 8, wherein the barrier metal is a laminated film of Ti and TiN.

10. The method for fabricating a semiconductor device of claim 8, wherein the barrier metal is formed by ALD (Atomic Layer Deposition).

11. The method for fabricating a semiconductor device of claim 8, wherein the conductive film is made of W, Cu, or Al.

12. A method for fabricating a semiconductor device, comprising:
forming a gate pattern on a substrate and forming a source/drain in the vicinity of the gate pattern;
forming an etch stop film, which covers the gate pattern and the source/drain, on the substrate;
forming an interlayer insulating film on the etch stop film;
forming a mask pattern on the interlayer insulating film;
etching the interlayer insulating film to form a contact hole that exposes the source/drain, wherein a polymer is generated in the contact hole in a process of etching the interlayer insulating film;
ashing the mask pattern;
removing the polymer by performing etching using hydrogen gas, nitrogen gas or a mixture of hydrogen and nitrogen before etching the etch stop film; and
etching the etch stop film.

13. The method for fabricating a semiconductor device of claim 12, wherein the steps for removing the polymer comprise removing part of the polymer using a first processing condition, and removing remaining polymer using a second processing condition that is different from the first processing condition.

14. The method for fabricating a semiconductor device of claim 12, further comprising forming a barrier metal that covers a side wall and a bottom surface of the contact hole after the step of etching the etch stop film, and thereafter forming a contact by filling the contact hole with a conductive film.

15. The method for fabricating a semiconductor device of claim 14, wherein the barrier metal is formed by ALD.

16. In a method of fabricating a semiconductor device that comprises at least a gate pattern on a substrate, a source/drain in the vicinity of the gate pattern, and a shared contact hole that exploses the gate pattern and the source/drain, and wherein the shared contact hole is formed by the sequential steps of: (a) forming an etch stop film on the gate pattern and the source/drain; (b) forming an interlayer insulating film on the etch stop film; and (c) etching the interlayer insulating film to form the contact hole whereby a polymer may be formed on the etch stop film along the surface of the contact hole, the improvement comprising: treating the surface of the contact hole with a treatment gas selected from hydrogen gas, nitrogen gas, and a mixture of hydrogen and nitrogen to remove the polymer from the surface of the etch stop film prior to carrying out a step of etching the etch stop film

17. The improvement of claim 16 wherein the steps for treating the contact hole to remove the polymer consist of: (i) a first polymer removal step; and (ii) a second polymer removal step that differs from the first polymer removal step (i) with respect to one or more of the treatment gas used, the processing atmospheres used, or the temperatures used.

18. A semiconductor device fabricated according to the method of claim 16.

19. A semiconductor device fabricated according to the method of claim 17.

20. A semiconductor device fabricated according to the method of claim 17 and further comprising a barrier metal formed by ALD along the surface of the contact hole and a conductive film filling the contact hole to form a contact.
